(19) United States
(12) Patent Application Publication
(10) Pub. No.: US 2020/0326399 A1
(43) Pub. Date: Oct. 15, 2020

(54) MAGNETIC SENSOR MODULE

(71) Applicants: Asahi Kasei Microdevices Corporation, Tokyo (JP); TDK Corporation, Tokyo (JP)

(72) Inventors: Masanori YOSHIDA, Tokyo (JP); Yoshitaka OKUTSU, Tokyo (JP); Kazuhiro ISHIDA, Tokyo (JP); Kazuya WATANABE, Tokyo (JP); Hiraku HIRABAYASHI, Tokyo (JP); Masanori SAKAI, Tokyo (JP)

(73) Assignees: Asahi Kasei Microdevices Corporation, Tokyo (JP); TDK Corporation, Tokyo (JP); TDK Corporation, Tokyo (JP)

(21) Appl. No.: 16/912,718

(22) Filed: Jun. 26, 2020

Related U.S. Application Data
(63) Continuation of application No. PCT/JP2018/047987, filed on Dec. 26, 2018.

(30) Foreign Application Priority Data
Dec. 27, 2017 (JP) 2017-252117

(51) Int. Cl. G01R 35/00; H01L 25/18; H01L 23/00; G01R 33/02; G01R 33/09

(52) U.S. Cl. CPC G01R 35/005; H01L 25/18; H01L 24/48; H01L 2224/48227; G01R 33/0206; G01R 33/09; H01L 2224/48145; H01L 24/49

(57) ABSTRACT

An object is to provide a magnetic sensor module reducing influence of heat generated from a coil on a magnetic sensor. A conventional method requires, on a magnetic sensor chip, multiple temperature measuring circuits corresponding to multiple magnetic sensors, and many pads for connection to an IC chip. Therefore, the problem is increase in size of the sensor chip mounting the sensors and in manufacturing cost. Provided is a magnetic sensor module comprising an IC chip including a first coil, a first pad connected to one end of the coil, and a second pad to the other end; a magnetic sensor chip disposed on the IC chip's surface, including a first magnetic sensor detecting first axial magnetism; a first external output terminal; a first conductive wire for connecting the first pad and terminal; a second external output terminal; and a second conductive wire for connecting the second pad and terminal.

The contents of the following Japanese patent application (s) are incorporated herein by reference:

NO. 2017-252117 filed in JP on Dec. 27, 2017, and

NO. PCT/JP2018/047987 filed on Dec. 26, 2018

### BACKGROUND

### 1. Technical Field

The present invention relates to a magnetic sensor module.

### 2. Related Art

In order to maintain accuracy of a magnetic sensor, it is preferably to calibrate sensitivity even during an operation. Therefore, known is a method of supplying constant current to a sensitivity adjusting coil embedded in a magnetic sensor chip to generate a known magnetic field, and measuring the same to adjust sensitivity of a magnetic sensor during an operation.

A first aspect of the present invention provides a magnetic sensor module comprising an IC chip including a first coil, a first pad connected to one end of the first coil, and a second pad connected to the other end of the first coil; a magnetic sensor chip disposed on a surface of the IC chip and including a first magnetic sensor that detects magnetism in a first axial direction; a first external output terminal; a first conductive wire for connecting the first pad and the first external output terminal; a second external output terminal; and a second conductive wire for connecting the second pad and the second external output terminal.

The summary of the present invention does not necessarily describe all necessary features of the present invention. The present invention may also be a sub-combination of the features described above.

### BRIEF DESCRIPTION OF THE DRAWINGS

FIG. 1 is a block diagram for illustrating functions of a magnetic sensor module 10 of a present embodiment.

FIG. 2 is a schematic view of the magnetic sensor module 10 in accordance with the present embodiment.

FIG. 3 is a plan view of an IC chip 200 in accordance with the present embodiment.

FIG. 4 is a plan view of a first coil 210 and a second coil 220 in accordance with the present embodiment.

FIG. 5 is a plan view of a third coil 230 in accordance with the present embodiment.

FIG. 6 is a plan view of a magnetic sensor chip 100 in accordance with the present embodiment.

FIG. 7 shows an example of an equivalent circuit of a first magnetic sensor 110 and the like in accordance with the present embodiment.

FIG. 8 is a schematic view of a vertical cross section of the magnetic sensor module 10 along a cross section S (dashed-dotted line) shown in FIG. 2.

FIG. 9 shows an example of a processing flow of the magnetic sensor module 10 of the present embodiment.

### DESCRIPTION OF EXEMPLARY EMBODIMENTS

Hereinafter, the present invention will be described through embodiments of the invention. However, the embodiments do not limit the invention defined in the claims. Also, all combinations of features described in the embodiments are not necessarily essential to solutions of the invention.

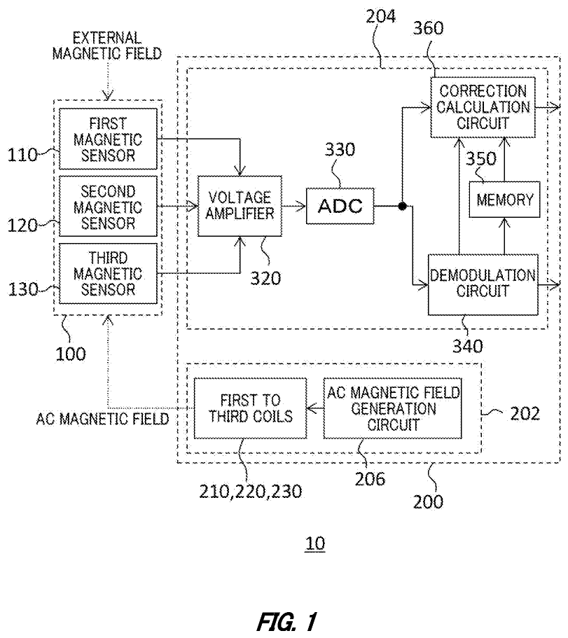

FIG. 1 is a block diagram for illustrating functions of a magnetic sensor module 10 of a present embodiment. The magnetic sensor module 10 in accordance with the present embodiment applies a uniform calibration magnetic field to a magnetic sensor by a coil embedded in an IC chip, thereby adjusting sensitivity of the magnetic sensor. The magnetic sensor module 10 comprises a magnetic sensor chip 100, and an IC chip 200. As described later, the magnetic sensor module 10 further comprises a mounting substrate 300 and the like, which are omitted in descriptions of FIG. 1.

The magnetic sensor chip 100 measures an external magnetic field. The magnetic sensor chip 100 may include one or more magnetic sensors, and detect magnetisms in one or more axial directions by the magnetic sensors. For example, the magnetic sensor chip 100 includes a first magnetic sensor 110, a second magnetic sensor 120, and a third magnetic sensor 130.

As an example, the first magnetic sensor 110 may detect magnetism in a first axial direction, the second magnetic sensor 120 may detect magnetism in a second axial direction different from the first axis, and the third magnetic sensor 130 may detect magnetism in a third axial direction orthogonal to the first axis and the second axis. The first magnetic sensor 110, the second magnetic sensor 120, and the third magnetic sensor 130 output voltage signals corresponding to magnetism detection results to the IC chip 200.

The IC chip 200 processes signals from the magnetic sensor chip 100, and adjusts sensitivities of the magnetic sensors by applying a calibration magnetic field to the magnetic sensor chip 100. For example, the IC chip 200 comprises a sensitivity adjusting unit 202 that adjusts sensitivities of one or more magnetic sensors of the magnetic sensor chip 100, and a signal processing unit 204 that processes signals from the magnetic sensor chip 100.

The sensitivity adjusting unit 202 includes an AC magnetic field generation circuit 206, and one or more coils (for example, a first coil 210, a second coil 220, and a third coil 230) each provided in correspondence to each of one or more magnetic sensors of the magnetic sensor chip 100.

The AC magnetic field generation circuit 206 sequentially applies calibration current having different polarities to each of the coils. For example, the AC magnetic field generation circuit 206 applies AC calibration current to each of the first coil 210, the second coil 220, and the third coil 230, thereby causing the first coil 210, the second coil 220, and the third coil 230 to generate AC calibration magnetic fields. Thereby, each of the first magnetic sensor 110, the second magnetic sensor 120, and the third magnetic sensor 130 detects each of the AC calibration magnetic fields, and outputs an AC voltage signal corresponding to a magnetism detection result to the signal processing unit 204.

As described later, the first coil 210 and the second coil 220 may be applied with common current, thereby generating the calibration magnetic fields at the same time. Alternatively, the first coil 210 and the second coil 220 may be applied independently with current, thereby generating independently the calibration magnetic fields.

The signal processing unit 204 includes a voltage amplifier 320, an AD converter 330, a demodulation circuit 340, a memory 350, and a correction calculation circuit 360.

The voltage amplifier 320 receives the voltage signals from each of the first magnetic sensor 110, the second magnetic sensor 120, and the third magnetic sensor 130, and amplifies and outputs the same to the AD converter 330.

The AD converter 330 converts analog outputs from the voltage amplifier 320 into digital values, and supplies the same to the demodulation circuit 340 and the correction calculation circuit 360.

The demodulation circuit 340 converts an AC signal into a DC signal, and supplies the converted signal to the correction calculation circuit 360. Thereby, the demodulation circuit 340 converts AC signals originating from the AC voltage signals output by the first magnetic sensor 110, the second magnetic sensor 120 and the third magnetic sensor 130 upon the sensitivity adjustment, into DC signals. Also, the demodulation circuit 340 stores the converted DC signals in the memory 350, as initial sensitivities, in an inspection process and the like before shipment.

The correction calculation circuit 360 corrects sensitivities of the magnetic sensors. For example, the correction calculation circuit 360 acquires, from the demodulation circuit 340, the DC signals originating from the AC voltage signals output by the first magnetic sensor 110, the second magnetic sensor 120 and the third magnetic sensor 130 upon the sensitivity adjustment, compares the DC signals with the initial sensitivities read out from the memory 350, and determines sensitivity correction amounts.

Subsequently, the correction calculation circuit 360 acquires, from the AD converter 330, DC signals originating from external magnetic fields, as external magnetic field signals, corrects the same based on the determined sensitivity correction amounts, and outputs final output signals to an outside, as an output after sensitivity correction. A specific processing flow of the sensitivity correction will be described later.

According to the present embodiment, the IC chip 200 causes the first coil 210 to the third coil 230 to generate AC (alternating current) calibration magnetic fields. Therefore, it is possible to adjust the sensitivities of the first magnetic sensor 110 to the third magnetic sensor 130 during an operation, without interfering with the external magnetic fields.

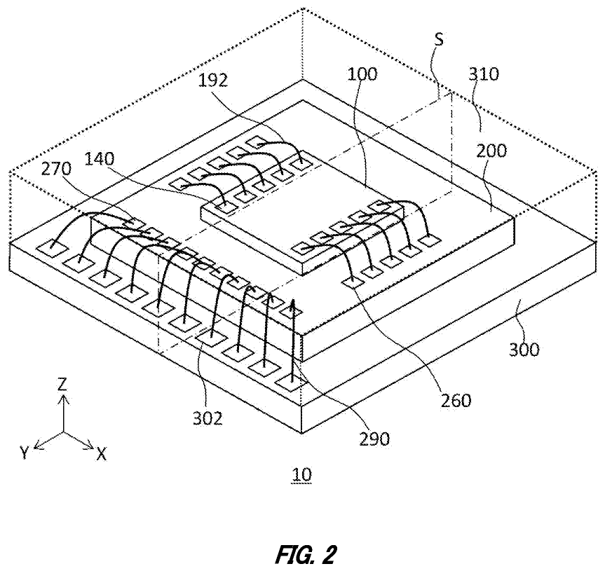

FIG. 2 is a schematic view of the magnetic sensor module 10 in accordance with the present embodiment. In FIG. 2, directions of respective sides of the magnetic sensor chip 100 and the IC chip 200 are set as X and Y directions, and a thickness direction of the magnetic sensor chip 100 and the IC chip 200 is set as a Z direction. The magnetic sensor module 10 of the present embodiment further comprises a mounting substrate 300 and a sealing resin 310, in addition to the magnetic sensor chip 100 and the IC chip 200.

As shown, the magnetic sensor chip 100 is disposed on a surface of the IC chip 200. Also, the magnetic sensor chip 100 has a plurality of (for example, 10) pads 140 on a first surface thereof. The first magnetic sensor 110, the second magnetic sensor 120, and the third magnetic sensor 130 embedded in the magnetic sensor chip 100 are connected to each of the pads 140, and are thus connected to the IC chip 200 via the pads 140.

The IC chip 200 has pads 260 and pads 270 on a first surface thereof. For example, the pads 260 may be disposed in the vicinity of the magnetic sensor chip 100, on the first surface of the IC chip 200. The IC chip 200 may have, for example, the 10 (ten) pads 260. For example, the IC chip 200 are connected to the ten pads 140 on the magnetic sensor chip 100 via the ten pads 260 and conductive wires 192. The conductive wire 192 may be formed by wire bonding.

The pads 270 are used for connection with the mounting substrate 300 on which the magnetic sensor module 10 is mounted For example, the IC chip 200 may have the ten pads 270, as shown.

Also, each of the pads 270 is connected to each of a plurality of coils (for example, a first coil 210 to a third coil 230) in the IC chip 200. For example, the pads 270 may include a first pad connected to one end of the first coil 210, a second pad connected to one end of the second coil 220, a third pad connected to one end of the third coil 230, and a fourth pad connected to the other end of the third coil 230. Thereby, the first coil 210 to the third coil 230 are connected to the mounting substrate 300.

On a first surface of the mounting substrate 300, the IC chip 200 is mounted. The mounting substrate 300 may be a printed board having a lead frame incorporated therein. The mounting substrate 300 may have pads 302 on the first surface, as a part of the lead frame. For example, the mounting substrate 300 may have ten pads 302 each of which is connected to each of the ten pads 270 of the IC chip 200.

The mounting substrate 300 may have a plurality of external output terminals on a backside, as a part of the lead frame. For example, the mounting substrate 300 may have ten external output terminals (not shown) provided in correspondence to the ten pads 302. In this case, each of the ten pads 302 and each of the ten external output terminals (not shown) may be connected through a wire (not shown) and a via (not shown) provided on the surface of the mounting substrate 300.

The plurality of (for example, ten) external output terminals may include at least a first external output terminal connected to one end of the first coil 210, a second external output terminal connected to the other end of the second coil 220, a third external output terminal connected to one end of the third coil 230, and a fourth external output terminal connected to the other end of the third coil 230. In this case, the other end of the first coil 210 and one end of the second coil 220 may be connected to each other in the IC chip 200.

Herein, the first external output terminal and the third external output terminal may be power supply terminals that are connected to a power supply such as a constant current source, and the second external output terminal and the fourth external output terminal may be ground terminals that are connected to a ground.

The pads 302 are connected to the pads 270 of the IC chip 200 by conductive wires 290. The conductive wire 290 may be formed by wire bonding. The conductive wire 290 may include a first conductive wire for connecting the first pad and the first external output terminal, a second conductive wire for connecting the second pad and the second external output terminal, a third conductive wire for connecting the third pad and the third external output terminal, and a fourth conductive wire for connecting the fourth pad and the fourth external output terminal.

The sealing resin 310 seals the module as a whole, thereby fixing the respective components. For example, the sealing resin 310 seals the magnetic sensor chip 100, the IC chip 200 and the mounting substrate 300.

As shown in FIG. 2, a planar shape (a shape on the XY plane) of the IC chip 200 is larger than a planar shape of the magnetic sensor chip 100, and encompasses the planar shape of the magnetic sensor chip 100. That is, a length of each side of the IC chip 200 on the plane is larger than a length of each side of the magnetic sensor chip 100. Also, a planar shape of the mounting substrate 300 is larger than the planar shape of the IC chip 200, and encompasses the planar shape of the IC chip 200. That is, a length of each side of the mounting substrate 300 on the plane is larger than a length of each side of the IC chip 200.

According to the magnetic sensor module 10 of the present embodiment, heat generated from the coils in the IC chip 200 is transferred along the pads 270, the conductive wires 290, the pads 302 and the lead frame of the mounting substrate 300, and is finally radiated from the external output terminals provided on the backside of the mounting substrate 300. According to the magnetic sensor module 10 of the present embodiment, it is not necessary to individually dispose temperature sensors or the like in the vicinity of each of the magnetic sensors. Therefore, according to the magnetic sensor module 10 of the present embodiment, it is possible to reduce an influence of the heat generated from the coils on the magnetic sensor chip 100 while reducing a size of the magnetic sensor chip 100.

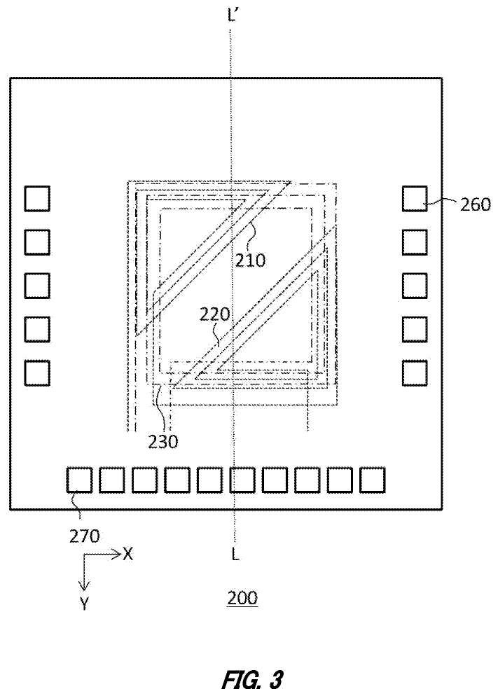

FIG. 3 is a plan view of the IC chip 200 seen from above in accordance with the present embodiment. In the meantime, when the first coil 210, the second coil 220, and the third coil 230 are disposed in the IC chip 200, they are invisible from above. However, in FIG. 2, positions of the coils on the XY plane are shown with broken lines. Herein, the first coil 210 and the second coil 220 are shown with the broken lines, and the third coil 230 is shown with the dashed-dotted line.

As shown, the first coil 210, the second coil 220, and the third coil 230 are provided in the IC chip 200 in the vicinity of a center thereof. As described later, the first coil 210 and the second coil 220, and the third coil 230 may be provided in different layers in the IC chip 200.

For example, the first coil 210 and the second coil 220 may be provided at least partially in an uppermost metal layer of a plurality of metal layers embedded in the IC chip 200, and the third coil 230 may be provided at least partially in a metal layer below the first coil 210 and the second coil 220. In the meantime, the uppermost metal layer may be provided on the surface of the IC chip 200, so that the first coil 210 and the second coil 220 may be exposed on the surface of the IC chip 200.

The metal layer in which the first coil 210 and the second coil 220 is provided may be a metal layer having the lowest sheet resistance value of the plurality of metal layers embedded in the IC chip 200. The metal layer in which the third coil 230 is provided may be a metal layer having the lowest sheet resistance value of the plurality of metal layers embedded in the IC chip 200. For example, the metal layer in which the first coil 210, the second coil 220 and/or the third coil 230 is provided may be a metal layer including aluminum or copper.

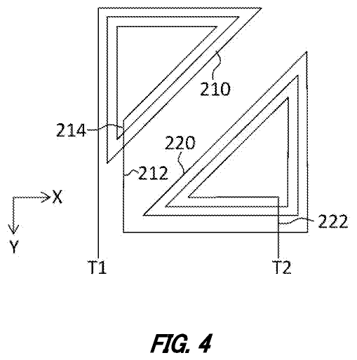

FIG. 4 is a plan view of the first coil 210 and the second coil 220 in accordance with the present embodiment. The first coil 210 and the second coil 220 may each have a planar shape including three or more sides. For example, the first coil 210 and the second coil 220 may each have a triangular shape (as an example, an isosceles right triangle) as shown in FIG. 4.

Each of the first coil 210 and the second coil 220 may also be a spiral coil. The first coil 210 and the second coil 220 may be connected by a connection wire 212 so that directions of currents flowing through both the coils are opposite to each other. That is, one end of the first coil 210 is connected to the first pad via a terminal T1, and the other end is connected to the second coil 220. One end of the second coil 220 is connected to the first coil 210, and the other end is connected to the second pad via a terminal T2. Thereby, the other end of the first coil 210 is connected to the second pad via the second coil 220, and one end of the second coil 220 is connected to the first pad via the first coil 210.

For example, in FIG. 4, the current introduced from the terminal T1 may flow through the first coil 210 in a clockwise direction, flow through the second coil 220 in a counterclockwise direction, and flow out from the terminal T2. As an example, one end T1 of the first coil 210 may be connected to a constant current source via a switch in the IC chip 200. Also, one end T2 of the second coil 220 may be connected to a ground via the switch in the IC chip 200, the second pad (one of the pads 270) and the second external output terminal.

Also, one end T1 of the first coil 210 is connected to the first pad (one of the pads 270) via the constant current source in the IC chip 200. Therefore, the heat generated from the first coil 210 and the second coil 220 due to the energization is transferred to the first pad and the second pad, and is finally radiated from the first external output terminal and the second external output terminal of the mounting substrate 300.

The connection wire 212 may include an intersection portion 214 that intersects with the first coil 210. The intersection portion 214 may be provided in a metal layer (for example, the layer in which the third coil 230 is provided or yet another metal layer) different from the metal layer in which the first coil 210 is provided, and the first coil 210 and the intersection portion 214 may be interlayer connected by a via or the like. An intersection portion 222 that intersects with the second coil 220 may be provided between the second coil 220 and one end T2. The intersection portion 222 may be provided in a metal layer (for example, the layer in which the third coil 230 is provided or yet another metal layer) different from the metal layer in which the second coil 220 is provided, and the second coil 220 and the intersection portion 222 may be interlayer connected by a via or the like.

In the meantime, instead of the shape shown in FIG. 4, the first coil 210 and the second coil 220 may not be connected to each other and may independently cause the current to flow therethrough. In this case, the first coil 210 and the second coil 220 may each have a similar terminal configuration to the third coil 230, which will be described later.

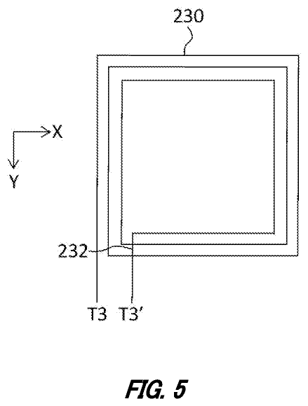

FIG. 5 is a plan view of the third coil 230 in accordance with the present embodiment. The third coil 230 may have a planar shape including three or more sides. For example, the third coil 230 may have a rectangular shape (as an example, a square shape) as shown in FIG. 4.

The third coil 230 may also be a spiral coil. For example, one end T3 of the third coil 230 may be connected to the ground via the switch in the IC chip 200, the third pad (one of the pads 270) and the third external output terminal. One end T3′ of the third coil 230 may be connected to the constant current source in the IC chip 200 via the switch in the IC chip 200.

Also, the other end T3′ of the third coil 230 is connected to the fourth pad (one of the pads 270) via the constant current source in the IC chip 200. Therefore, the heat generated from the third coil 230 due to the energization is transferred to the third pad and the fourth pad, and is finally radiated from the third external output terminal and the fourth external output terminal of the mounting substrate 300.

An intersection portion 232 may be provided between the third coil 230 and one end T3′. The intersection portion 232 may be provided in a metal layer (for example, the metal layer in which the first coil 210 and the second coil 220 are provided or a layer further below the metal layer in which the third coil 230 is provided) different from the metal layer in which the third coil 230 is provided, and the third coil 230 and the intersection portion 232 may be interlayer connected by a via or the like.

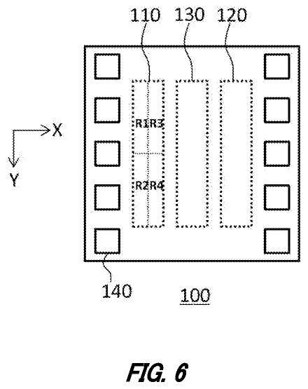

FIG. 6 is a plan view of the magnetic sensor chip 100 in accordance with the present embodiment. In the meantime, the first magnetic sensor 110, the second magnetic sensor 120, and the third magnetic sensor 130 are disposed in the magnetic sensor chip 100 and are thus usually invisible from above. However, in FIG. 6, positions of the sensors are shown with broken lines. Instead, the first magnetic sensor 110 to the third magnetic sensor 130 may be exposed on the surface of the magnetic sensor chip 100.

As shown, the first magnetic sensor 110, the third magnetic sensor 130, and the second magnetic sensor 120 each have a rectangular shape extending in the Y direction, and are aligned in corresponding order in the X direction. For example, the first magnetic sensor 110 may be configured as an X-axis magnetic sensor of which a magnetic sensing axis is the X-axis, the second magnetic sensor 120 may be configured as a Y-axis magnetic sensor of which a magnetic sensing axis is the Y-axis, and the third magnetic sensor 130 may be configured as a Z-axis magnetic sensor of which a magnetic sensing axis is the Z-axis. In this case, the Z-axis magnetic sensor is arranged in a central part of the magnetic sensor chip 100.

Herein, the first magnetic sensor 110 and the second magnetic sensor 120 may be sensitivity-adjusted by the calibration magnetic fields from the first coil 210 and the second coil 220. Also, the third magnetic sensor 130 may be sensitivity-adjusted by the calibration magnetic field from the third coil 230.

Each of the first magnetic sensor 110, the second magnetic sensor 120, and the third magnetic sensor 130 (hereinafter, also collectively referred to as “first magnetic sensor 110 and the like”) may include a magneto-resistive element configuring a Wheatstone bridge circuit. For example, each of the first magnetic sensor 110 and the like may be a magneto-resistive element including a region R1, a region R2, a region R3, and a region R4 divided along the X direction and the Y direction. Each of the first magnetic sensor 110 and the like may be connected to terminals at each of a boundary between the region R1 and the region R2, a boundary between the region R1 and the region R3, a boundary between the region R2 and the region R4, and a boundary between the region R3 and the region R4.

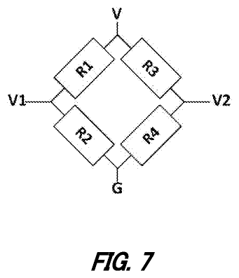

FIG. 7 shows an example of an equivalent circuit of each of the first magnetic sensor 110 and the like configuring a Wheatstone bridge circuit, in accordance with the present embodiment. The resistor R1 to the resistor R4 in FIG. 7 correspond to the regions R1 to R4 in FIG. 6. As shown, in each of the first magnetic sensor 110 and the like, one end of the resistor R1, one end of the resistor R3 and a power supply terminal are connected, and the power supply terminal is connected to a constant voltage source, so that a voltage V is applied to the power supply terminal. The other end of the resistor R1, one end of the resistor R2 and a positive electrode output terminal are connected, so that an output voltage V1 is output from the positive electrode output terminal. The other end of the resistor R3, one end of the resistor R4 and a negative electrode output terminal are connected, so that an output voltage V2 is output from the negative electrode output terminal. The other end of the resistor R2, the other end of the resistor R4 and a ground terminal are connected, and the ground terminal is connected to a ground G.

Each of the first magnetic sensor 110 and the like outputs a difference between the output voltages V1 and V2, as a sensor output. The ground terminals of the first magnetic sensor 110 and the like may be connected with a wire layer in the magnetic sensor chip 100.

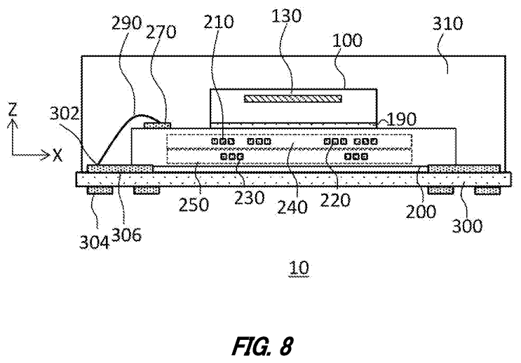

FIG. 8 is a schematic view of a vertical cross section of the magnetic sensor module 10 along a cross section S (dashed-dotted line) shown in FIG. 2. The cross section S of FIG. 2 corresponds to a line L-L′ in FIG. 3. As shown, the magnetic sensor chip 100 and the IC chip 200 are bonded to each other by an adhesive layer 190. Also, the first coil 210 and the second coil 220 are formed in a first metal layer 240 that is the uppermost metal layer in the IC chip 200. The third coil 230 is formed in a second metal layer 250 that is a metal layer below the first metal layer 240 in the IC chip 200.

The mounting substrate 300 has a lead frame 306, and the IC chip 200 is mounted on the lead frame 306. On an upper surface of an outer peripheral part of the lead frame 306, the pads 302 for connection with the conductive wires 290 are provided. On a backside of the lead frame 306, external output terminals 304 including the first external output terminal to the fourth external output terminal are provided. The mounting substrate 300 may be a land grid array (LGA) substrate having lands as the external output terminals 304.

Each of the first magnetic sensor 110, the second magnetic sensor 120 and the third magnetic sensor 130 may be disposed in a position in which the magnetic field generated from each of the first coil 210, the second coil 220 and the third coil 230 increases. For example, the first magnetic sensor 110 and the second magnetic sensor 120 may be disposed so as to overlap at least partially positions in a vertical direction (for example, the Z direction) in which the magnetic fields generated by the first coil 210 and the second coil 220 are greatest.

For example, the first magnetic sensor 110 and the second magnetic sensor 120 may be disposed so as to include a position of about ⅓ (for example, 110 to 120 μm) of a distance (as an example, 360 μm) of a line connecting centers of gravity of the first coil 210 and the second coil 220. Also, the third magnetic sensor 130 may be disposed so as to overlap at least partially a position in a vertical direction (for example, the Z direction) in which the magnetic field generated by the third coil 230 is greatest.

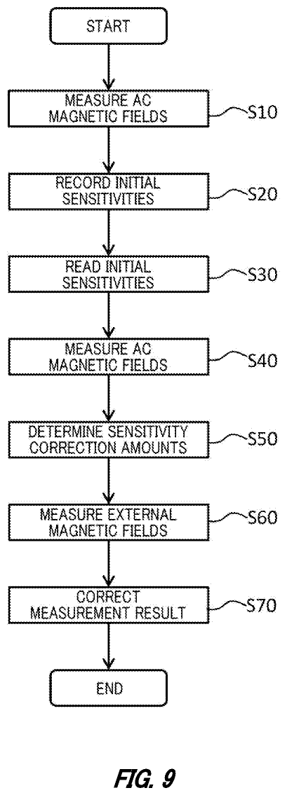

FIG. 9 shows an example of a processing flow of the magnetic sensor module 10 of the present embodiment. The magnetic sensor module 10 can perform the accurate sensitivity correction during an operation by executing processing of S10 to S70 in FIG. 9.

Herein, the processing of S10 and S20 may be executed in an inspection process before shipment. The processing of S30 and thereafter may be executed at any timing after start of use of the magnetic sensor module 10. For example, the processing of S30 and thereafter may be executed at periodic timing or in response to a user's request, after start of use of the magnetic sensor module 10.

First, in S10, the magnetic sensor module 10 measures AC magnetic fields. For example, the AC magnetic field generation circuit 206 applies the AC calibration current from the constant current source to the first coil 210 and the second coil 220. Thereby, the first coil 210 and the second coil 220 generate AC calibration magnetic fields in the XY plane. The first magnetic sensor 110 having the X-axis as a magnetic sensing axis and the second magnetic sensor 120 having the Y-axis as a magnetic sensing axis output, to the voltage amplifier 320, an X-output voltage corresponding to the detected X direction magnetic field and a Y-output voltage corresponding to the detected Y direction magnetic field.

At this time, the heat generated from the first coil 210 and the second coil 220 is transferred to the external output terminals 304 exposed from the lead frame 306 on the backside of the mounting substrate 300 via a conduction path including the pads 270, the conductive wires 290, and the pads 302, and is radiated from the external output terminals 304. Therefore, an influence of the heat generated from the first coil 210 and the second coil 220 on the magnetic sensor chip 100 is reduced.

The voltage amplifier 320 amplifies the X-output voltage and Y-output voltage, and outputs the amplified X-output voltage and Y-output voltage to the AD converter 330. The AD converter 330 converts the X-output voltage and Y-output voltage, which are analog signals from the voltage amplifier 320, into digital values and supplies the same to the demodulation circuit 340. The demodulation circuit 340 converts the X-output voltage and Y-output voltage, which are digital AC signals, into DC signals, and sets the same as an initial sensitivity in the X direction and an initial sensitivity in the Y direction.

Also, the AC magnetic field generation circuit 206 applies the AC calibration current from the constant current source to the third coil 230. Thereby, the third coil 230 generates an AC calibration magnetic field in a plane including the Z-axis. The third magnetic sensor 130 having the Z-axis as a magnetic sensing axis outputs a Z-output voltage corresponding to the detected Z direction magnetic field to the voltage amplifier 320.

At this time, the heat generated from the third coil 230 is transferred to the external output terminals 304 exposed from the lead frame 306 on the backside of the mounting substrate 300 via the conduction path including the pads 270, the conductive wires 290, and the pads 302, and is radiated from the external output terminals 304. Therefore, an influence of the heat generated from the third coil 230 on the magnetic sensor chip 100 is also reduced.

The voltage amplifier 320 amplifies the Z-output voltage, and outputs the amplified Z-output voltage to the AD converter 330. The AD converter 330 converts the Z-output voltage, which is an analog signal from the voltage amplifier 320, into a digital value and supplies the same to the demodulation circuit 340. The demodulation circuit 340 converts the Z-output voltage, which is a digital AC signal, into a DC signal and sets the same as an initial sensitivity in the Z direction.

Then, in S20, the demodulation circuit 340 stores the initial sensitivities acquired in S10 in the memory 350. In the meantime, the magnetic sensor module 10 may also perform the processing of S10 and S20 in the Z direction after performing the processing of S10 and S20 in the X direction and the Y direction.

In S30, the correction calculation circuit 360 reads out the initial sensitivities from the memory 350. The correction calculation circuit 360 may read out the initial sensitivities in the X direction, the Y direction and the Z direction from the memory 350.

Then, in S40, the magnetic sensor module 10 measures AC magnetic fields. The magnetic sensor module 10 may measure the AC magnetic fields in a similar manner to S10, and acquire the obtained DC signals as current sensitivities. For example, the magnetic sensor module 10 may acquire the current sensitivities in the X direction, the Y direction and the Z direction.

Then, in S50, the correction calculation circuit 360 performs the sensitivity correction. For example, the correction calculation circuit 360 compares the initial sensitivities read in S30 and the current sensitivities obtained in S40, and determines sensitivity correction amounts. For example, the correction calculation circuit 360 may acquire, as the sensitivity correction amount, (initial sensitivity)/(current sensitivity) or (initial sensitivity)−(current sensitivity). The correction calculation circuit 360 may acquire the sensitivity correction amount in each of the X direction, the Y direction and the Z direction.

Then, in S60, the magnetic sensor module 10 measures external magnetic fields. For example, the magnetic sensor module 10 stops the operation of the AC magnetic field generation circuit 206, and causes the magnetic sensor chip 100 to measure the external magnetic fields. For example, the first magnetic sensor 110, the second magnetic sensor 120, and the third magnetic sensor 130 output the X-output voltage, the Y-output voltage, and the Z-output voltage to the voltage amplifier 320, respectively.

The voltage amplifier 320 amplifies each of the output voltages and outputs the same to the AD converter 330. The AD converter 330 converts the respective output voltages, which are analog signals from the voltage amplifier 320, into digital values, and supplies the same to the correction calculation circuit 360, as the external magnetic field measurement values in the X direction, the Y direction, and the Z direction.

Then, in S70, the correction calculation circuit 360 corrects a measurement result of the external magnetic fields obtained in S60 by the sensitivity correction amounts obtained in S50. For example, the correction calculation circuit 360 corrects each of the external magnetic field measurement values in the X direction, the Y direction and the Z direction by the sensitivity correction amounts in each of the X direction, the Y direction and the Z direction. As an example, the correction calculation circuit 360 may execute the correction by multiplying or adding the sensitivity correction amounts in the corresponding directions by or to the external magnetic field measurement values in each of the directions.

In this way, according to the magnetic sensor module 10, it is possible to accurately correct the sensitivity of the magnetism measurement during the operation. In particular, according to the magnetic sensor module 10 of the present embodiment, since the sensitivity adjusting coil is not mounted in the magnetic sensor chip 100, it is possible to make the magnetic sensor chip 100 small and to save the cost.

Also, according to the magnetic sensor module 10 of the present embodiment, since a temperature sensor is not mounted in the magnetic sensor chip 100 and the heat generated from the coils is radiated via the external output terminals, it is possible to reduce the influence of the heat generated from the coils on the magnetic sensor chip 100 while reducing the size of the magnetic sensor chip 100.

In the meantime, for convenience of descriptions, in FIGS. 2, 3, 8 and the like, the circuit of the signal processing unit 204 and the AC magnetic field generation circuit 206 included in the IC chip 200 are not shown. However, it should be noted that the IC chip 200 has the circuits and any other circuit in any positions, as required.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

### EXPLANATION OF REFERENCES

10: magnetic sensor module
100: magnetic sensor chip
110: first magnetic sensor
120: second magnetic sensor
130: third magnetic sensor
140: pad
190: adhesive layer
192: conductive wire
200: IC chip
202: sensitivity adjusting unit
204: signal processing unit
206: AC magnetic field generation circuit
210: first coil
212: connection wire
214: intersection portion
220: second coil
222: intersection portion
230: third coil
232: intersection portion
240: first metal layer
250: second metal layer
260: pad
270: pad
290: conductive wire
300: mounting substrate
302: pad
304: external output terminal
306: lead frame
310: sealing resin
320: voltage amplifier
330: AD converter
340: demodulation circuit
350: memory
360: correction calculation circuit

What is claimed is:

1. A magnetic sensor module comprising:
an IC chip including a first coil, a first pad connected to one end of the first coil, and a second pad connected to the other end of the first coil;
a magnetic sensor chip disposed on a surface of the IC chip and including a first magnetic sensor that detects magnetism in a first axial direction;
a first external output terminal;
a first conductive wire for connecting the first pad and the first external output terminal;
a second external output terminal; and
a second conductive wire for connecting the second pad and the second external output terminal.

2. The magnetic sensor module according to claim 1, wherein
the first coil is provided at least partially in a metal layer having the lowest sheet resistance value of the IC chip.

3. The magnetic sensor module according to claim 1, wherein
the first coil is provided at least partially in an uppermost metal layer of the IC chip.

4. The magnetic sensor module according to claim 1, wherein
the IC chip further includes a second coil,
one end of the second coil is connected to the other end of the first coil,
the other end of the second coil is connected to the second pad,
the other end of the first coil is connected to the second pad via the second coil, and
the magnetic sensor chip includes a second magnetic sensor that detects magnetism in a second axial direction.

5. The magnetic sensor module according to claim 4, wherein
the second external output terminal is a ground terminal.

6. The magnetic sensor module according to claim 4, wherein
the second coil is provided at least partially in a metal layer having the lowest sheet resistance value of the IC chip.

7. The magnetic sensor module according to claim 4, wherein
the second coil is provided at least partially in an uppermost metal layer of the IC chip.

8. The magnetic sensor module according to claim 4, wherein
the IC chip further includes a third coil, a third pad connected to one end of the third coil, and a fourth pad connected to the other end of the third coil,
the magnetic sensor chip includes a third magnetic sensor that detects magnetism in a third axial direction, and
the magnetic sensor module further comprises:
a third external output terminal,
a third conductive wire for connecting the third pad and the third external output terminal,
a fourth external output terminal, and
a fourth conductive wire for connecting the fourth pad and the fourth external output terminal.

9. The magnetic sensor module according to claim 8, wherein
the fourth external output terminal is a ground terminal.

10. The magnetic sensor module according to claim 8, wherein
the third coil is provided at least partially in a metal layer having the lowest sheet resistance value of the IC chip.

11. The magnetic sensor module according to claim 8, wherein
the third coil is provided at least partially in a metal layer below the first coil and the second coil of the IC chip.

12. The magnetic sensor module according to claim 8, wherein
the first magnetic sensor, the second magnetic sensor and the third magnetic sensor each includes a magneto-resistive element configuring a Wheatstone bridge circuit.

13. The magnetic sensor module according to claim 5, wherein
the first magnetic sensor and the second magnetic sensor are disposed so as to overlap at least partially positions in which magnetic fields generated by the first coil and the second coil are greatest.

14. The magnetic sensor module according to claim 2, wherein
the first coil is provided at least partially in an uppermost metal layer of the IC chip.

15. The magnetic sensor module according to claim 2, wherein
the IC chip further includes a second coil,
one end of the second coil is connected to the other end of the first coil,
the other end of the second coil is connected to the second pad,
the other end of the first coil is connected to the second pad via the second coil, and
the magnetic sensor chip includes a second magnetic sensor that detects magnetism in a second axial direction.

16. The magnetic sensor module according to claim 3, wherein
the IC chip further includes a second coil,
one end of the second coil is connected to the other end of the first coil,
the other end of the second coil is connected to the second pad,
the other end of the first coil is connected to the second pad via the second coil, and
the magnetic sensor chip includes a second magnetic sensor that detects magnetism in a second axial direction.

17. The magnetic sensor module according to claim 14, wherein
the IC chip further includes a second coil,
one end of the second coil is connected to the other end of the first coil,
the other end of the second coil is connected to the second pad,
the other end of the first coil is connected to the second pad via the second coil, and
the magnetic sensor chip includes a second magnetic sensor that detects magnetism in a second axial direction.

18. The magnetic sensor module according to claim 15, wherein
the second external output terminal is a ground terminal.

19. The magnetic sensor module according to claim 16, wherein
the second external output terminal is a ground terminal.

20. The magnetic sensor module according to claim 5, wherein
the second coil is provided at least partially in a metal layer having the lowest sheet resistance value of the IC chip.
